(19) United States
(12) Patent Application Publication
(10) Pub. No.: US 2009/0224321 A1
(43) Pub. Date: Sep. 10, 2009

(54) SEMICONDUCTOR DEVICE AND METHOD OF MANUFACTURING SEMICONDUCTOR DEVICE

(75) Inventor: Ryuta TSUCHIYA, Tokyo (JP)

Correspondence Address: MILES & STOCKBRIDGE PC, 1751 PINNACLE DRIVE, SUITE 500, MCLEAN, VA, 22102-3833, US

(73) Assignee: RENESAS TECHNOLOGY CORP

(21) Appl. No.: 12/394,553

(22) Filed: Feb. 27, 2009

(30) Foreign Application Priority Data
Mar. 6, 2008 (JP) 2008-055829

(51) Int. Cl. H01L 27/12; H01L 21/782

(52) U.S. Cl. 257/351; 438/154; 257/E27.112; 257/E21.7

(57) ABSTRACT

Provided are a semiconductor device capable of improving the drive capacity of a MOS transistor even if the SOI layer is thinned; and a manufacturing method of the device. In a NMOS transistor formed in a NMOS formation region, a source/drain region is formed to penetrate through a buried oxide film and reach a threshold voltage controlling diffusion layer of a semiconductor substrate. In a PMOS transistor formed in a PMOS formation region, a source/drain region is formed to penetrate through a buried oxide film and reach a threshold voltage control diffusion layer of the semiconductor substrate.

### CROSS-REFERENCE TO RELATED APPLICATIONS

The disclosure of Japanese Patent Application No. 2008-55829 filed on Mar. 6, 2008 including the specification, drawings and abstract is incorporated herein by reference in its entirety.

### BACKGROUND OF THE INVENTION

The present invention relates to a semiconductor device having a MOS transistor formed on a SOI (Silicon on Insulator) substrate; and a manufacturing method thereof.

The term “MOS” used for a metal/oxide/conductor stack structure in the past is said to be a coined acronym consisting of the initial letters of Metal-Oxide-Semiconductor. In particular, a field-effect transistor having a MOS structure (which will hereinafter be called “MOS transistor”, simply), however, uses improved materials for its gate insulating film and gate electrode from the viewpoint of recent improvement in integration degree or manufacturing process.

For example, a MOS transistor uses, as a material for its gate electrode, polycrystalline silicon instead of a metal mainly from the viewpoint of forming source/drain in self alignment. In addition, from the viewpoint of improving the electrical properties, a material having a high dielectric constant is used for its gate insulating film, but the material is not necessarily limited to oxides.

The term “MOS” is therefore not necessarily limited to the metal/oxide/semiconductor stack structure and the invention is not premised on such a limitation. In accordance with the technological common sense, the term “MOS” as used herein not only is an abbreviation based on its origin but also widely embraces a conductor/insulator/semiconductor stack structure.

A SOI device is known to have many excellent characteristics such as low power consumption, high-speed operation, and latch-up free operation. In particular, a fully depleted SOI device (such as MOS transistor having, below the channel thereof, a SOI layer (body region) which is fully depleted when power is ON) can keep a low impurity concentration of the SOI layer and therefore provide such an advantage that fluctuations in the threshold voltage due to fluctuations in the impurity concentration which have become evident since the 65-nm generation can be reduced. Such SOI devices are disclosed, for example, in Japanese Patent Laid-Open No. 2005-251776 and T. Tsuchiya, et al., “Silicon on Thin BOX: A New Paradigm of The CMOSFET for Low-Power and High-Performance Application Featuring Wide-Range Back-Bias Control”, IEDM Tech., p. 631(2004).

A strain technology is, on the other hand, employed as a technology for enhancing the performance of CMOS devices. This technology improves the mobility by utilizing strain stress. Use of this technology enables enhancement of the drive capacity of a device. The strain technology can be classified roughly into two kinds, that is, a technology of making use of the stress of a SiN liner film and a technology of recessing a source/drain region to cause selective epitaxial growth of a material such as SiGe which is different in lattice constant from silicon (Si) and making use of the strain stress generated by the lattice strain. Either one of these two strain technologies may be used or both of them may be used in combination. It is difficult to enhance the drive capacity of CMOS devices of the 65-nm generation and beyond only by miniaturization of devices so that application of the strain technology has an important meaning.

FIG. 38 is a cross-sectional view illustrating the structure of a CMOS semiconductor device which is a conventional fully depleted SOI device.

As illustrated in this diagram, in a SOI structure comprised of a semiconductor substrate 1, a buried oxide film 4, and an element isolation insulating film 2, a NMOS formation region A1 and a PMOS formation region A2 are isolated by the element isolation insulating films 2 and 2 which penetrate through a SOI layer 3 and the buried oxide film 4 and reach a part of the semiconductor substrate 1. In these NMOS formation region A1 and PMOS formation region A2, a NMOS transistor Q30 and a PMOS transistor Q40 are formed, respectively.

First, the NMOS transistor Q30 will be described. Source and drain regions 55 and 55 are formed selectively in the SOI layer 3 of the NMOS formation region A1 and a gate electrode 52 is formed, via a gate oxide film 51, over a channel region 54 which is an upper layer portion of the SOI layer 3 between the N type source and drain regions 55 and 55. Over the side surfaces of the gate electrode 52, sidewalls 53 are formed. The source/drain region 55 has, thereover, a Ni-silicide region 57. A P-type threshold voltage controlling diffusion layer 58 is formed over the semiconductor substrate 1 below the channel region 54 and the source and drain regions 55 and 55, with the buried oxide film 4 therebetween. In such a manner, the NMOS transistor Q30 having, as the main components thereof, the channel region 54, the source/drain region 55, the gate oxide film 51, and the gate electrode 52 is formed in the NMOS formation region A1.

Next, the PMOS transistor Q40 will be described. Source and drain regions 65 and 65 are formed selectively in the SOI layer 3 of the PMOS formation region A2 and a gate electrode 62 is formed, via a gate oxide film 61, over a channel region 64 which is an upper layer portion of the SOI layer 3 between P type source and drain regions 65 and 65. Over the side surfaces of the gate electrode 62, sidewalls 63 are formed. The source/drain region 65 has, thereover, a Ni-silicide region 67. An N-type threshold voltage controlling diffusion layer 68 is formed over the semiconductor substrate 1 below the channel region 64 and the source and drain regions 65 and 65, with the buried oxide film 4 therebetween. In such a manner, the PMOS transistor Q40 having, as the main components thereof, the channel region 64, the source/drain region 65, the gate oxide film 61, and the gate electrode 62 is formed in the PMOS formation region A2.

### SUMMARY OF THE INVENTION

In order to run the semiconductor device as illustrated in FIG. 38 as a fully depleted type device, the thickness of the SOI layer 3 must be reduced. Described specifically, the SOI layer 3 must be thinned to about one-third of the gate length. This means that in devices of the 65-nm generation and beyond, the thickness of the SOI layer 3 must be reduced to 20 nm or less. As a result of the reduction in thickness, it becomes difficult to cause selective epitaxial growth of SiGe or the like in a recessed source/drain region because the SOI layer 3 is too thin.

Although fully depleted type SOI devices have excellent characteristics such as low power consumption, high-speed operation, and small fluctuations in threshold voltage, they have a problem that a reduction in the thickness of the SOI layer makes it very difficult to employ a strain application technology.

The present invention is made to overcome the above-described problem. An object of the present invention is to provide a semiconductor device with a MOS transistor having a SOI structure and capable of having improved drive capacity even if the thickness of the SOI layer is reduced; and a manufacturing method of the device.

According to one embodiment of the present invention, a source/drain region of a MOS transistor formed over a SOI structure which region applies to a channel region a strain for improving the drive capacity is formed by removing a buried oxide film.

According to this Embodiment, it is possible to enhance the drive capacity of a MOS transistor by forming a source/drain region for applying to a channel region a strain for improving the drive capacity and thus employing a strain application technology. The drive capacity can be enhanced further because the source/drain region is formed by removing the buried oxide film. As a result, the drive capacity of the MOS transistor can be improved even if the SOI layer becomes thinner.

### BRIEF DESCRIPTION OF DRAWINGS

FIG. 1 is a cross-sectional view illustrating the structure of a CMOS semiconductor device of Embodiment 1 of the present invention having a SOI structure;

FIG. 2 is a cross-sectional view illustrating a manufacturing method of the semiconductor device according to Embodiment 1;

FIG. 3 is a cross-sectional view illustrating the manufacturing method of the semiconductor device according to Embodiment 1;

FIG. 4 is a cross-sectional view illustrating the manufacturing method of the semiconductor device according to Embodiment 1;

FIG. 5 is a cross-sectional view illustrating the manufacturing method of the semiconductor device according to Embodiment 1;

FIG. 6 is a cross-sectional view illustrating the manufacturing method of the semiconductor device according to Embodiment 1;

FIG. 7 is a cross-sectional view illustrating the manufacturing method of the semiconductor device according to Embodiment 1;

FIG. 8 is a cross-sectional view illustrating the manufacturing method of the semiconductor device according to Embodiment 1;

FIG. 9 is a cross-sectional view illustrating the manufacturing method of the semiconductor device according to Embodiment 1;

FIG. 10 is a cross-sectional view illustrating the manufacturing method of the semiconductor device according to Embodiment 1;

FIG. 11 is a cross-sectional view illustrating the manufacturing method of the semiconductor device according to Embodiment 1;

FIG. 12 is a cross-sectional view illustrating the manufacturing method of the semiconductor device according to Embodiment 1;

FIG. 13 is a cross-sectional view illustrating the manufacturing method of the semiconductor device according to Embodiment 1;

FIG. 14 is a cross-sectional view illustrating the manufacturing method of the semiconductor device according to Embodiment 1;

FIG. 15 is a cross-sectional view illustrating the structure of a CMOS semiconductor device of Embodiment 2 of the present invention having a SOI structure;

FIG. 16 is a cross-sectional view illustrating a manufacturing method of the semiconductor device according to Embodiment 2;

FIG. 17 is a cross-sectional view illustrating the manufacturing method of the semiconductor device according to Embodiment 2;

FIG. 18 is a cross-sectional view illustrating the manufacturing method of the semiconductor device according to Embodiment 2;

FIG. 19 is a cross-sectional view illustrating the manufacturing method of the semiconductor device according to Embodiment 2;

FIG. 20 is a cross-sectional view illustrating the manufacturing method of the semiconductor device according to Embodiment 2;

FIG. 21 is a cross-sectional view illustrating the manufacturing method of the semiconductor device according to Embodiment 2;

FIG. 22 is a cross-sectional view illustrating the structure of a CMOS semiconductor device of Embodiment 3 of the present invention having a SOI structure;

FIG. 23 is a cross-sectional view illustrating a manufacturing method of the semiconductor device according to Embodiment 3;

FIG. 24 is a cross-sectional view illustrating the manufacturing method of the semiconductor device according to Embodiment 3;

FIG. 25 is a cross-sectional view illustrating the manufacturing method of the semiconductor device according to Embodiment 3;

FIG. 26 is a cross-sectional view illustrating the manufacturing method of the semiconductor device according to Embodiment 3;

FIG. 27 is a cross-sectional view illustrating the manufacturing method of the semiconductor device according to Embodiment 3;

FIG. 28 is a cross-sectional view illustrating the manufacturing method of the semiconductor device according to Embodiment 3;

FIG. 29 is a circuit diagram illustrating the configuration of a typical SRAM memory cell;

FIG. 30 is a cross-sectional view illustrating the structure of a CMOS semiconductor device of Embodiment 4 of the present invention having a SOI structure;

FIG. 31 is a cross-sectional view illustrating the structure of a CMOS semiconductor device of Embodiment 5 of the present invention having a SOI structure;

FIG. 32 is a cross-sectional view illustrating the structure of a CMOS semiconductor device of Embodiment 6 of the present invention having a SOI structure;

FIG. 33 is a cross-sectional view illustrating a manufacturing method of the semiconductor device according to Embodiment 6;

FIG. 34 is a cross-sectional view illustrating the manufacturing method of the semiconductor device according to Embodiment 6;

FIG. 35 is a cross-sectional view illustrating the manufacturing method of the semiconductor device according to Embodiment 6;

FIG. 36 is a cross-sectional view illustrating the manufacturing method of the semiconductor device according to Embodiment 6;

FIG. 37 is a schematic view illustrating the circuit configuration of a system LSI which is an application example of the present invention; and

FIG. 38 is a cross-sectional view illustrating the structure of a CMOS semiconductor device which is a conventional fully-depleted SOI device.

### DETAILED DESCRIPTION OF THE PREFERRED EMBODIMENTS

### Embodiment 1

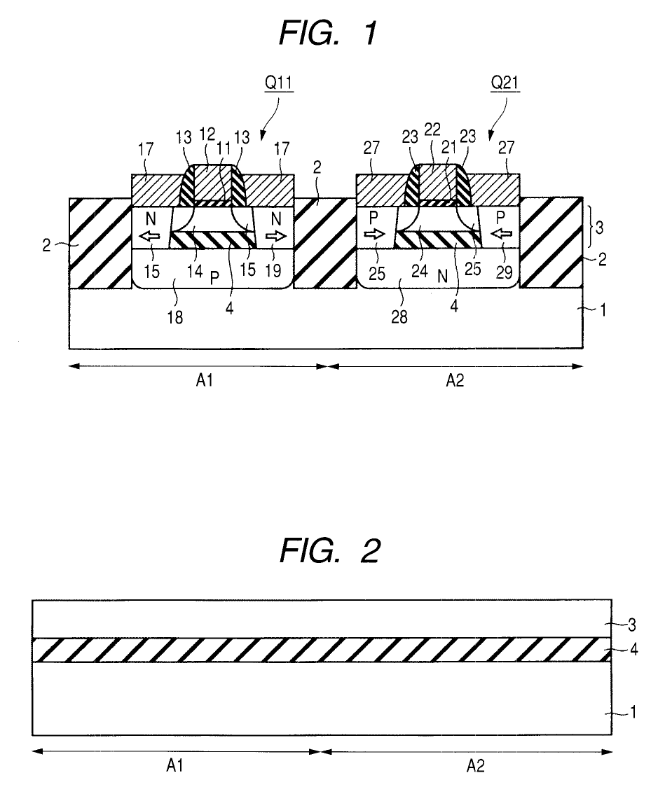

FIG. 1 is a cross-sectional view illustrating the structure of a CMOS semiconductor device of Embodiment 1 of the present invention formed over a SOI structure.

As illustrated in this drawing, in a SOI structure having a semiconductor substrate 1, a buried oxide film 4, and an element isolation insulating film 2, provided are a NMOS formation region A1 and a PMOS formation region A2 which are independent from each other, isolated by the element isolation insulating films 2 and 2 formed to penetrate through a SOI layer 3 and the buried oxide film 4 and reach a part of the semiconductor substrate 1. In these NMOS formation region A1 and PMOS formation region A2, a NMOS transistor Q11 and a PMOS transistor Q21 are formed, respectively.

First, the NMOS transistor Q11 will be described. N type source and drain regions 15 and 15 are formed selectively in the SOI layer 3 of the NMOS formation region A1. The source/drain region 15 penetrates through the buried oxide film 4 and reaches a threshold voltage controlling diffusion layer 18 of the semiconductor substrate 1. In the SOI layer 3, extension regions 16 and 16 are formed adjacently to these source and drain regions 15 and 15 in the direction of a channel.

A gate electrode 12 having an entirely silicided surface is formed, via a gate oxide film 11, over a channel region 14 which is an upper layer portion of the SOI layer 3 between the extension regions 16 and 16. The gate electrode 12 has, on the side surface thereof, a sidewall 13. The source/drain region 15 has, as an upper layer portion thereof, a Ni silicide region 17.

In the NMOS formation region A1, the P type threshold voltage controlling diffusion layer 18 is formed as an upper layer portion of the semiconductor substrate 1 below the buried oxide film 4 and the source/drain region 15. In other words, the threshold voltage controlling diffusion layer 18 is formed as an upper layer portion of the semiconductor substrate 1 including a region opposite to the channel region 14 and the extension regions 16 and 16, with the buried oxide film 4 therebetween.

Thus, in the NMOS formation region A1, the NMOS transistor Q11 having, as main components thereof, the channel region 14, the source/drain region 15, the extension region 16, the gate oxide film 11, and the gate electrode 12 is formed.

Next, the PMOS transistor Q21 will be described. P type source and drain regions 25 and 25 are formed selectively in a SOI layer 3 of the PMOS formation region A2. The source/drain region 25 penetrates through a buried oxide film 4 and reaches a threshold voltage controlling diffusion layer 28 of the semiconductor substrate 1. In the SOI layer 3, extension regions 26 and 26 are formed adjacently to these source and drain regions 25 and 25 in the direction of a channel.

A gate electrode 22 having an entirely silicided surface is formed, via a gate oxide film 21, over a channel region 24 which is an upper layer portion of the SOI layer 3 between the extension regions 26 and 26. The gate electrode 22 has, on the side surface thereof, a sidewall 23. The source/drain region 25 has, as an upper layer portion thereof, a Ni silicide region 27.

In the PMOS formation region A2, an N type threshold voltage controlling diffusion layer 28 is formed as an upper layer portion of the semiconductor substrate 1 below the buried oxide film 4 and the source/drain region 25. In other words, the threshold voltage controlling diffusion layer 28 is formed as an upper layer portion of the semiconductor substrate 1 including a region opposite to the channel region 24 and the extension regions 26 and 26 with the buried oxide film 4 therebetween.

Thus, in the PMOS formation region A2, the PMOS transistor Q21 having, as main components thereof, the channel region 24, the source/drain region 25, the extension region 26, the gate oxide film 21, and the gate electrode 22 is formed.

FIGS. 2 to 14 are cross-sectional views illustrating a manufacturing method of the semiconductor device of Embodiment 1. The manufacturing method of the semiconductor device of Embodiment 1 will next be described based on these drawings.

First, as illustrated in FIG. 2, a SOI substrate (SOI structure) having a stack structure comprised of a semiconductor substrate 1, a buried oxide film 4, and a SOI layer 3 having silicon as a constituent material is prepared.

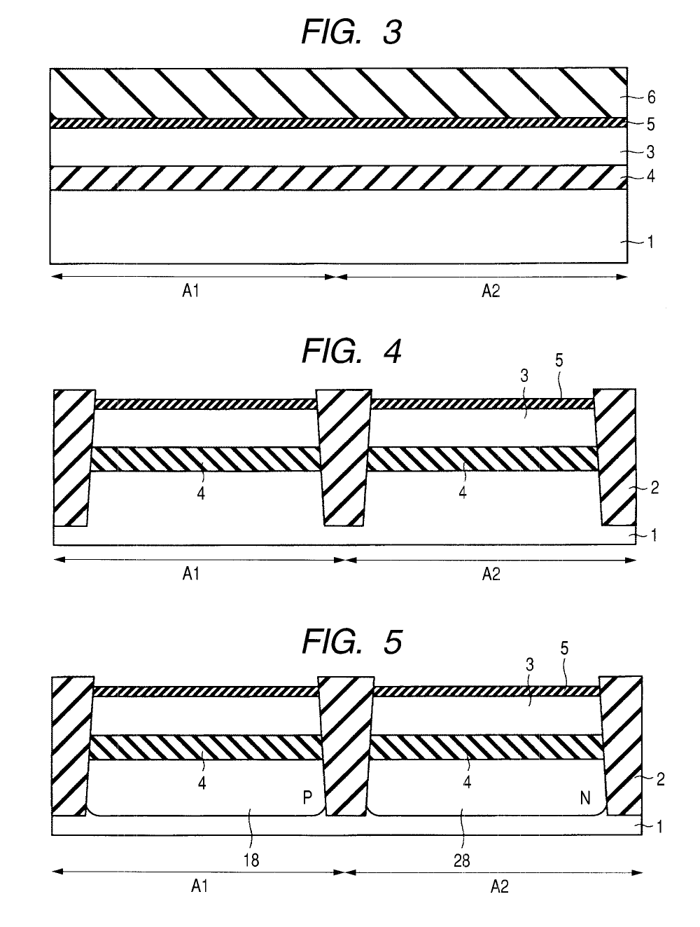

Then, as illustrated in FIG. 3, after formation of a silicon oxide film (SiO₂) 5 over the entire surface, a silicon nitride film (SiN) 6 is formed over the silicon oxide film 5.

As illustrated in FIG. 4, with a patterned silicon nitride film 6 (not illustrated) as a mask, the buried oxide film 4 and a part of the upper layer portion of the semiconductor substrate 1 are removed from a desired region to selectively form element isolation insulating films 2 and 2 which will be STI (Shallow Trench Isolation). As a result, a NMOS formation region A1 and a PMOS formation region A2 isolated from each other between the element isolation insulating films 2 and 2 are defined. The patterned silicon nitride film 6 is then removed.

As illustrated in FIG. 5, in the NMOS formation region A1, a P type threshold voltage controlling diffusion layer 18 is formed by introducing P type impurities into the upper layer portion of the semiconductor substrate 1 below the buried oxide film 4 by ion implantation via the silicon oxide film 5, the SOI layer 3 and the buried oxide film 4. In a similar manner, in the PMOS formation region A2, an N type threshold voltage controlling diffusion layer 28 is formed by introducing N type impurities into the upper layer portion of the semiconductor substrate 1 below the buried oxide film 4 by ion implantation via the silicon oxide film 5, the SOI layer 3, and the buried oxide film 4.

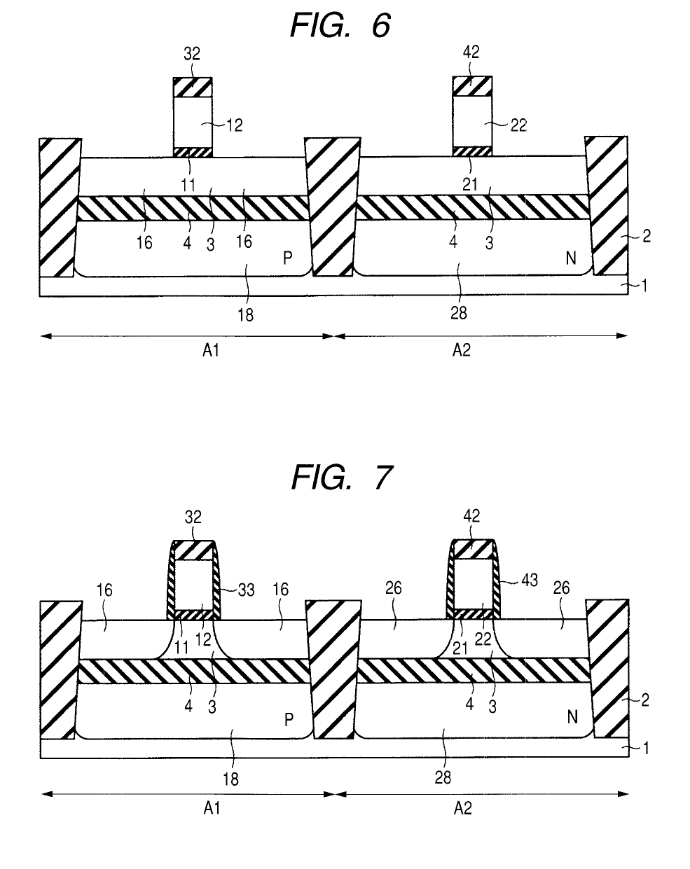

As illustrated in FIG. 6, after removal of the silicon oxide film 5, a gate structure for NMOS having a stack structure comprised of a gate oxide film 11, a gate electrode 12, and a gate protective film 32 is formed selectively over the SOI layer 3 in the NMOS formation region A1. In a similar manner, a gate structure for PMOS having a stack structure comprised of a gate oxide film 21, a gate electrode 22, and a gate protective film 42 is formed selectively over the SOI layer 3 in the PMOS formation region A2. As a material for the gate oxide film 11 (12), SiON or high-K oxide film can be given as a candidate.

As illustrated in FIG. 7, side spacers 33 and 43 are formed over the side surfaces of the gate structures for NMOS and PMOS, respectively. In the NMOS formation region A1, with the gate electrode and the side spacer 33 for NMOS as a mask, ion implantation is then performed to introduce N type impurities into the SOI layer 3 to form an N type extension region 16. In a similar manner, in the PMOS formation region A2, with the gate electrode and the side spacer 43 for PMOS as a mask, ion implantation is then performed to introduce P type impurities into the SOI layer 3 to form a P type extension region 26.

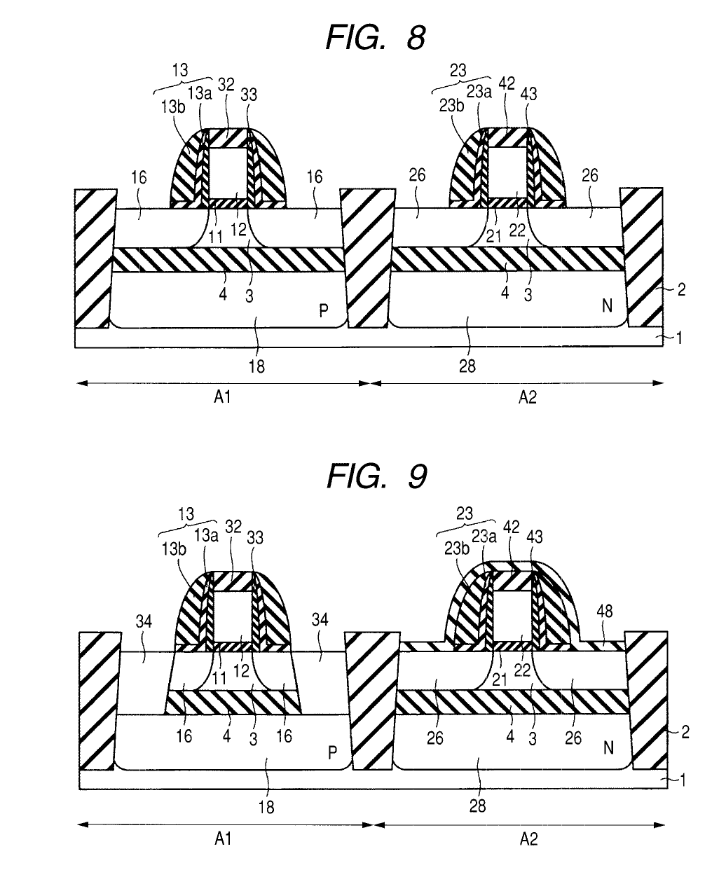

As illustrated in FIG. 8, a sidewall 13 comprised of a silicon oxide film 13a and a silicon nitride film 13b is formed over the side surface of the gate structure for NMOS including the side spacer 33, while a sidewall 23 comprised of a silicon oxide film 23a and a silicon nitride film 23b is formed over the side surface of the gate structure for PMOS including the side spacer 43.

As illustrated in FIG. 9, the SOI layer 3 is removed to expose the surface of the buried film 4 by etching or the like with the gate structure, the side spacer 33, and the side wall 13 for NMOS as a mask while covering the PMOS formation region A2 with a silicon oxide film 48 and exposing the NMOS formation region. Moreover, the buried oxide film 4 is also removed by dry etching or wet etching to expose the surface of the semiconductor substrate 1 (a threshold voltage controlling diffusion layer 18). As a result, in the NMOS formation region A1, a recess 34 penetrating the SOI layer 3 and the buried oxide film 4 can be obtained.

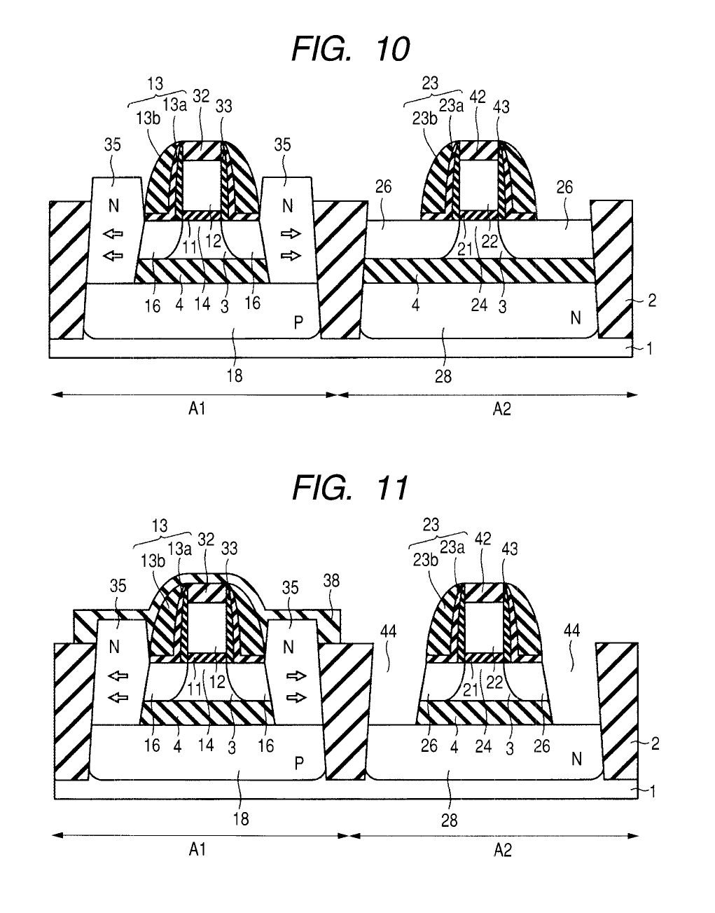

As illustrated in FIG. 10, after removal of the silicon oxide film 48, an SiC epitaxial growth region 35 is formed in a region including the inside of the recess 34 by causing selective epitaxial growth of a material, for example SiC having a smaller lattice constant than silicon (a material forming a channel region) with single crystal Si in the exposed surface of the semiconductor substrate 1 as a seed. SiC serves as a first strain application material, that is, a material for adding, to a channel region 14 which is a surface of the SOI layer 3 between the extension regions 16 and 16, a tensile stress for improving the drive capacity.

As illustrated in FIG. 11, the surface of the buried oxide film 4 is exposed by removing the SOI layer 3 by etching or the like with the gate structure, the side spacer 43, and the sidewall 23 for PMOS as a mask while covering the NMOS formation region A1 with a silicon oxide film 38 and exposing the PMOS formation region A2. The surface of the semiconductor substrate 1 (threshold voltage controlling diffusion layer 28) is exposed by removing also the buried oxide film 4 by dry etching or wet etching. As a result, in the PMOS formation region A2, a recess 44 penetrating the SOI layer 3 and the buried oxide film 4 can be obtained.

As illustrated in FIG. 12, after removal of the silicon oxide film 38, a SiGe epitaxial growth region 45 is formed in a region including the inside of the recess 44 by causing selective epitaxial growth of a material having a greater lattice constant (for example, SiGe) than silicon (a material forming a channel region) with single crystal Si of the exposed surface of the semiconductor substrate 1 as a seed. SiGe serves as a first strain application material, that is, a material adding, to a channel region 24 which is a surface of the SOI layer 3 between the extension regions 26 and 26, a compressive strain for improving the drive capacity.

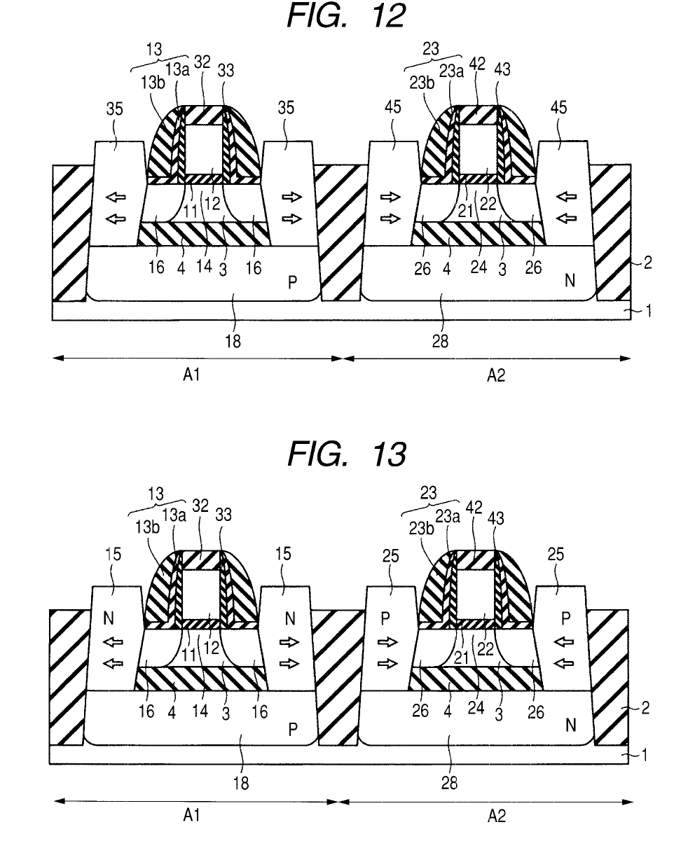

As illustrated in FIG. 13, an N type source/drain region 15 is then formed by selectively introducing N type impurities into the SiC epitaxial growth region 35 in the NMOS formation region A1. In a similar manner, a P type source/drain region 25 is formed by selectively introducing P type impurities into the SiGe epitaxial growth region 45 in the PMOS formation region A2. Then, annealing treatment such as RTA (Rapid Thermal Annealing) is performed.

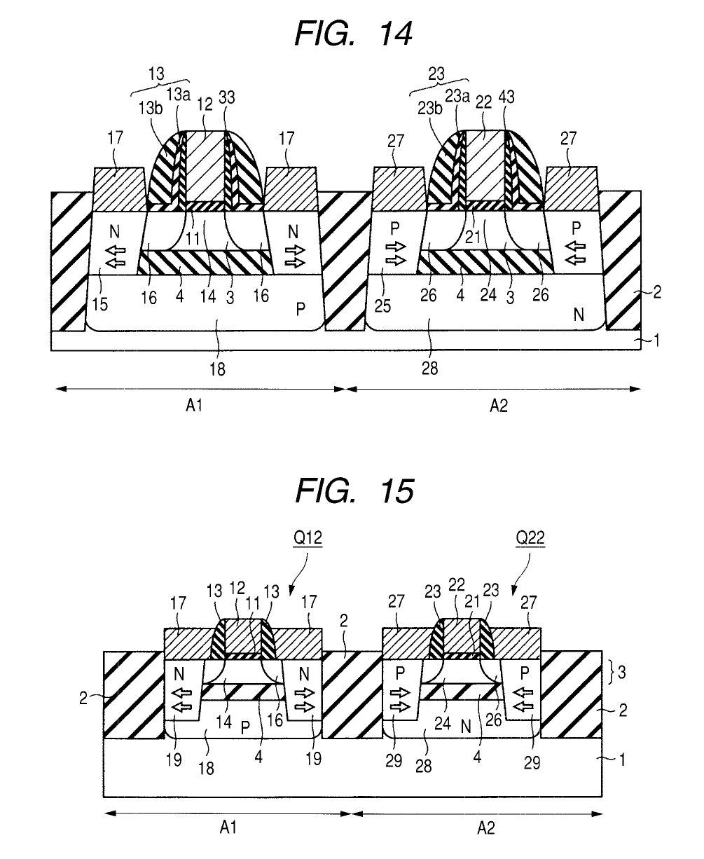

As illustrated in FIG. 14, after removal of the gate protective films 32 and 42, the upper layer portion of the source/drain region 15 and the gate electrode 12 are silicided to form a Ni silicide region 17 and the gate electrode 12 having an entirely silicided surface in the NMOS formation region A2. In a similar manner, in the PMOS formation region A2, the upper layer portion of the source/drain region 25 and the gate electrode 22 are silicided to form a Ni silicide region 27 and the gate electrode 22 having an entirely silicided surface.

As a result, manufacture of the semiconductor device of Embodiment 1 as illustrated in FIG. 1 is completed. The side spacers 33 and 43, the silicon oxide films 13a and 23a, and the silicon nitride films 13b and 23b illustrated in FIG. 14 are collectively illustrated as the sidewall 13.

Employment of an FUSI gate (FUSI: Fully Silicided Gate) structure for each of the gate electrode 12 and the gate electrode 22 is effective for raising the threshold voltage, thereby suppressing an off-leakage current.

Thus, the semiconductor device according to Embodiment 1 has, in the NMOS formation region A1 thereof, the source/drain region 15 having a tensile strain to the channel region 14 and, in the PMOS formation region A2, the source/drain region 25 having a compressive strain to the channel region 14. Since a tensile train can be applied to the NMOS transistor Q11 and a compressive strain can be applied to the PMOS transistor Q21, the drive capacity of both the NMOS transistor Q11 and the PMOS transistor Q21 can be enhanced

The source/drain regions 15 and 25 are formed to penetrate through the buried oxide film 4 so that the source/drain regions 15 and 25 can have a depth corresponding to the thicknesses of the SOI layer 3 and the buried oxide film 4. The stress (strain) to be applied can therefore be raised in proportion to the thickness of the buried oxide film 4. As a result, a MOS transistor having a source/drain region capable of enhancing the drive capacity can be formed by selective epitaxial growth from the surface of the semiconductor substrate 1 (threshold voltage controlling diffusion layers 18 and 28) even if the SOI layer 3 is thinned.

Moreover, since the semiconductor device according to Embodiment 1 has, due to the local presence of the buried oxide film 4 below the gate electrode 12 (22), a fully depleted type SOI structure and at the same time has, due to the presence of the threshold voltage controlling diffusion layer 18 (28), a pseudo double gate structure, the device is excellent in short channel characteristics.

The term “pseudo double gate structure” as used herein means a structure in which, in addition to the gate electrode 12 (22), the threshold voltage controlling diffusion layer 18 (28) and the buried oxide film 4 thereon function as a pseudo gate electrode and a pseudo gate insulating film, respectively.

In this Embodiment, a PN junction between the source/drain region 15 (25) and the semiconductor substrate 1 is located within the substrate by the diffusion treatment performed during formation of the source/drain region as illustrated in FIG. 13. Even if stacking faults occur in the epitaxial growth region 35 (45), there occurs no junction leakage which will otherwise occur due to the defect during epitaxial growth.

Thus, the semiconductor device according to Embodiment 1 is effective for achieving both miniaturization of the device and performance enhancement.

In the above-described manufacturing method of the semiconductor device according to Embodiment 1, the source/drain regions 15 and 25 are formed by, after selective epitaxial growth of the non-doped SiC epitaxial growth region 35 and the SiGe epitaxial growth region 45 (refer to FIGS. 9 to 12), impurities are introduced into these regions 35 and 45 by ion implantation (refer to FIG. 13).

Alternatively, the source/drain regions 15 and 25 may be formed directly during epitaxial growth by making use of selective epitaxial growth of doped SiC and doped SiGe.

### Embodiment 2

FIG. 15 is a cross-sectional view illustrating the structure of a CMOS semiconductor device according to Embodiment 2 of the present invention having a SOI structure.

As illustrated in this drawing, in a SOI structure having a semiconductor substrate 1, a buried oxide film 4, and an element isolation insulating film 2, a NMOS formation region A1 and a PMOS formation region A2 which are independent from each other, isolated by the element isolation insulating films 2 and 2 which penetrate through a SOI layer 3 and the buried oxide film 4, and reach a part of the semiconductor substrate 1. In these NMOS formation region A1 and PMOS formation region A2, a NMOS transistor Q12 and a PMOS transistor Q22 are formed, respectively.

First, the NMOS transistor Q12 will be described. N type source and drain regions 19 and 19 are formed selectively in the SOI layer 3 of the NMOS formation region A1. The source/drain region 19 penetrates through the buried oxide film 4 and reaches a part of a threshold voltage controlling diffusion layer 18 of the semiconductor substrate 1. In the SOI layer 3, extension regions 16 and 16 are formed adjacently to these source and drain regions 19 and 19 in the direction of a channel.

A gate electrode 12 having an entirely silicided surface is formed, via a gate oxide film 11, over a P type channel region 14 which is an upper layer portion of the SOI layer 3 between the extension regions 16 and 16. The gate electrode 12 has, on the side surface thereof, a sidewall 13. The source/drain region 19 has, as an upper layer portion thereof, a Ni silicide region 17.

In the NMOS formation region A1, a P type threshold voltage controlling diffusion layer 18 is formed as an upper layer portion of the semiconductor substrate 1 lying below the buried oxide film 4 and the source and drain regions 19 and 19. In other words, the threshold voltage controlling diffusion layer 18 is formed as an upper layer portion of the semiconductor substrate 1 including a region opposite to the channel region 14 and the extension regions 16 and 16, with the buried oxide film 4 therebetween.

Thus, in the NMOS formation region A1, the NMOS transistor Q12 having, as main components thereof, the channel region 14, the extension region 16, the source/drain region 19, the gate oxide film 11, and the gate electrode 12 is formed.

Next, the PMOS transistor Q22 will be described. P type source and drain regions 29 and 29 are formed selectively in a SOI layer 3 of the PMOS formation region A2. The source/drain region 29 penetrates through the buried oxide film 4 and reaches a part of a threshold voltage controlling diffusion layer 28 of the semiconductor substrate 1. In the SOI layer 3, extension regions 26 and 26 are formed adjacently to these source and drain regions 29 and 29 in the direction of a channel.

A gate electrode 22 having an entirely silicided surface is formed, via a gate oxide film 21, over a channel region 24 which is an upper layer portion of the SOI layer 3 between the extension regions 26 and 26. The gate electrode 22 has, on the side surface thereof, a sidewall 23. The source/drain region 29 has, as an upper layer portion thereof, a Ni silicide region 27.

In the PMOS formation region A2, a P type threshold voltage controlling diffusion layer 28 is formed as an upper layer portion of the semiconductor substrate 1 below the buried oxide film 4 and the source and drain regions 29 and 29. In other words, the threshold voltage controlling diffusion layer 28 is formed as an upper layer portion of the semiconductor substrate 1 including a region opposite to the channel region 24 and the extension regions 26 and 26, with the buried oxide film 4 therebetween.

Thus, in the PMOS formation region A2, the PMOS transistor Q22 having, as main components thereof, the channel region 24, the extension region 26, the source/drain region 29, the gate oxide film 21, and the gate electrode 22 is formed.

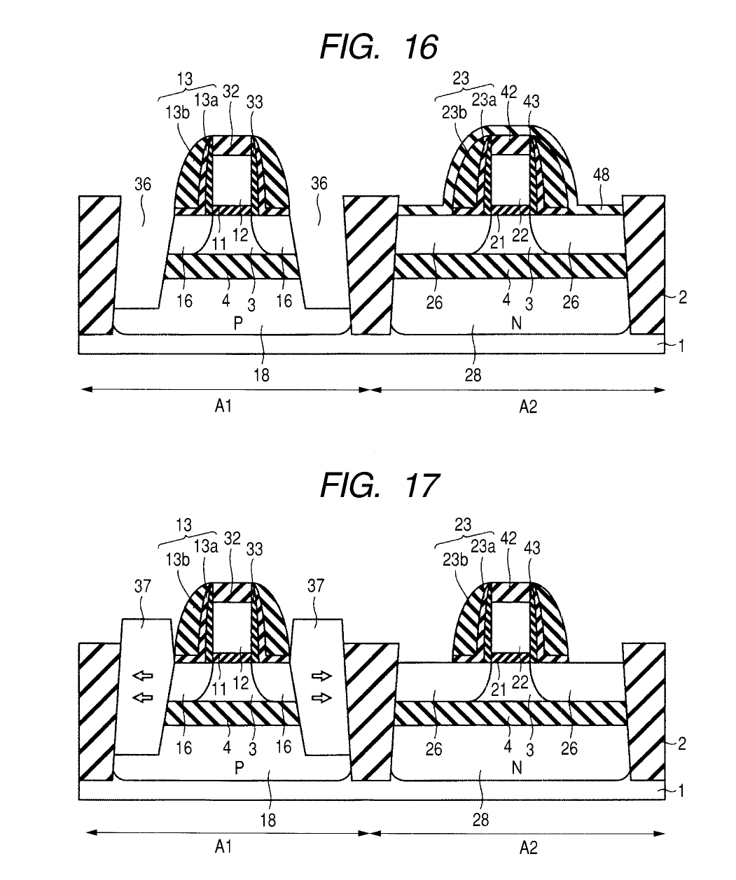

FIGS. 16 to 21 are cross-sectional views illustrating a manufacturing method of the semiconductor device of Embodiment 2. The manufacturing method of the semiconductor device of Embodiment 2 will next be described based on these drawings.

First, after similar manufacturing steps to those employed in Embodiment 1 as illustrated in FIGS. 2 to 8, the SOI layer 3 is removed to expose the surface of the buried oxide film 4 by etching or the like with the gate structures (11, 12, 32), the side spacer 33, and the sidewall 13 for NMOS as a mask while covering the PMOS formation region A2 with a silicon oxide film 48 and exposing the NMOS formation region A1. The buried oxide film 4 is also removed by dry etching or wet etching to expose the surface of the semiconductor substrate 1 (threshold voltage controlling diffusion layer 18). A part of the upper layer portion of the exposed semiconductor substrate 1 is removed by etching or the like.

As a result, in the NMOS formation region A1, a recess 36 penetrating through the SOI layer 3 and the buried oxide film 4 and reaching a part of the upper layer portion of the semiconductor substrate 1 can be obtained.

As illustrated in FIG. 17, an SiC epitaxial growth region 37 is formed in a region including the inside of the recess 34 by causing selective epitaxial growth of a material, for example, SiC having a smaller lattice constant than silicon with single crystal Si of the exposed surface of the semiconductor substrate 1 as a seed.

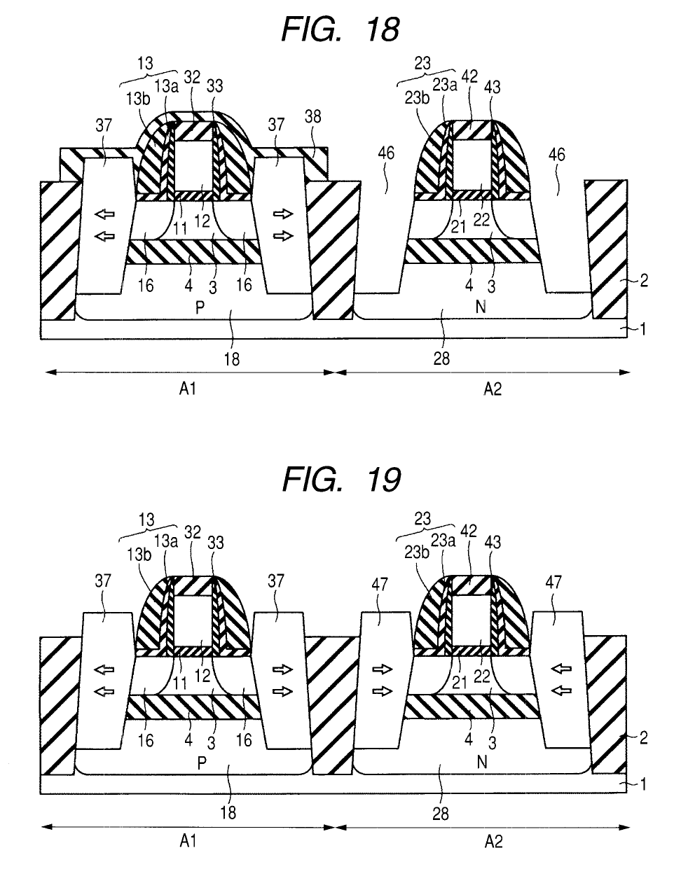

As illustrated in FIG. 18, the surface of the buried oxide film 4 is exposed by removing the SOI layer 3 by etching or the like with the gate structure, the side spacer 43, and the sidewall 23 for PMOS as a mask while covering the NMOS formation region A1 with a silicon oxide film 38 and exposing the PMOS formation region A2. Moreover, the surface of the semiconductor substrate 1 (threshold voltage controlling diffusion layer 28) is exposed by removing even the buried oxide film 4 by dry etching or wet etching. A part of the upper layer portion of the exposed semiconductor substrate 1 is then removed by etching or the like.

As a result, a recess 46 penetrating through the SOI layer 3 and the buried oxide film 4 and reaching a part of the upper layer portion of the semiconductor substrate 1 can be obtained in the PMOS formation region A2.

As illustrated in FIG. 19, a SiGe epitaxial growth region 47 is formed in a region including the inside of the recess 46 by causing selective epitaxial growth of a material, for example, SiGe having a greater lattice constant than silicon with single crystal Si of the exposed surface of the semiconductor substrate 1 as a seed.

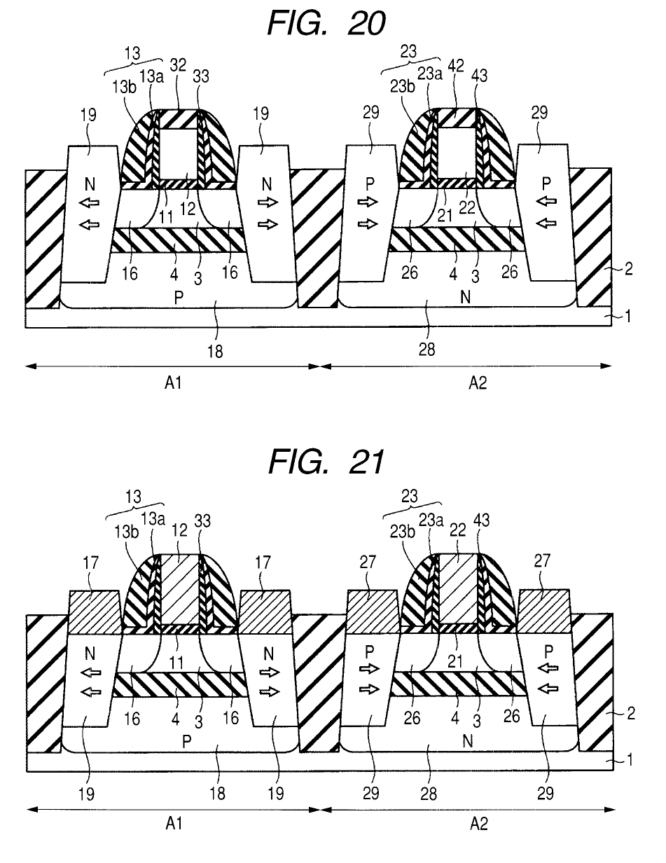

As illustrated in FIG. 20, an N type source/drain region 19 is then formed by introducing an N type impurity selectively into the SiC epitaxial growth region 37 in the NMOS formation region A1. In a similar manner, a P type source/drain region 29 is formed by introducing a P type impurity selectively into the SiGe epitaxial growth region 47 in the PMOS formation region A2. Annealing treatment such as RTA is then performed.

As illustrated in FIG. 21, after removal of the gate protective films 32 and 42, the upper layer portion of the source/drain region 19 and the gate electrode 12 are silicided to form a Ni silicide region 17 and the gate electrode 12 having an entirely silicided surface in the NMOS formation region A1. In a similar manner, the upper layer portion of the source/drain region 29 and the gate electrode 22 are silicided to form a Ni silicide region 27 and the gate electrode 22 having an entirely silicided surface in the PMOS formation region A2. As a result, manufacture of the semiconductor device of Embodiment 2 as illustrated in FIG. 15 is completed. It should be noted that the side spacers 33 and 43, the silicon oxide films 13a and 23a, and the silicon nitride films 13b and 23b illustrated in FIG. 21 are collectively illustrated as sidewalls 13 and 23 in FIG. 15.

Thus, in the semiconductor device of Embodiment 2, the source/drain region 19 having a tensile strain to the channel region 14 is formed in the NMOS formation region A1 and the source/drain region 29 having a compressive strain to the channel region 24 is formed in the PMOS formation region A2. Similar to Embodiment 1, since a tensile strain is applied to the NMOS transistor Q12 and a compressive strain can be applied to the PMOS transistor Q22, this embodiment is effective for enhancing the drive capacity of both the NMOS transistor Q12 and the PMOS transistor Q22.

The source/drain regions 19 and 29 are formed to penetrate through the buried oxide film 4 and reach a part of the upper layer portion of the semiconductor substrate 1 so that the source/drain regions 19 and 29 can have a depth corresponding to the thicknesses of the SOI layer 3 and the buried oxide film 4 and the removed thickness (removed thickness of the semiconductor) of the part of the upper layer portion of the semiconductor substrate 1. The stress (strain) to be applied can therefore be increased in proportion to the thickness of the buried oxide film 4 and the removed thickness of the semiconductor. As a result, a MOS transistor having a source/drain region capable of increasing the drive capacity over that of Embodiment 1 can be formed by selective epitaxial growth from the surface of the semiconductor substrate 1 (threshold voltage controlling diffusion layers 18 and 28) even if the SOI layer 3 is thinned.

Moreover, since the semiconductor device according to Embodiment 2 has, due to the local presence of the buried oxide film 4 below the gate electrode 12 (22), a fully depleted type SOI structure and at the same time, has, due to the presence of the threshold voltage controlling diffusion layer 18 (28), a pseudo double gate structure as in Embodiment 1, the device is excellent in short channel characteristics.

Also in Embodiment 2 as in Embodiment 1, there occurs no junction leakage due to defects during formation of the SiC epitaxial growth region 37 and the SiGe epitaxial growth region 47.

Thus, the semiconductor device according to Embodiment 2 is effective for achieving both miniaturization of the device and performance enhancement.

In the above-described manufacturing method of the semiconductor device according to Embodiment 2, after selective epitaxial growth of the non-doped SiC epitaxial growth region 37 and the SiGe epitaxial growth region 47 (refer to FIGS. 16 to 19), impurities are introduced into these regions 37 and 47 by ion implantation to form the source/drain regions 19 and 29 (refer to FIG. 20).

Alternatively, the source/drain regions 19 and 29 may be formed directly during epitaxial growth by making use of selective epitaxial growth of doped SiC and doped SiGe.

### Embodiment 3

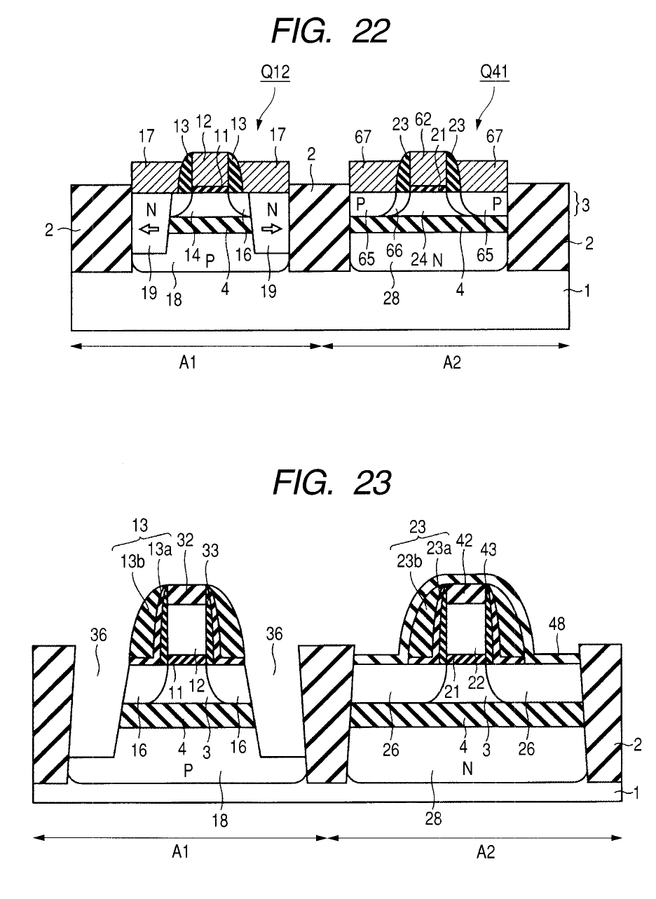

FIG. 22 is a cross-sectional view illustrating the structure of a CMOS semiconductor device of Embodiment 3 of the present invention having a SOI structure.

As illustrated in FIG. 22, in a SOI structure comprised of a semiconductor substrate 1, a buried oxide film 4, and an element isolation insulating film 2, formed are a NMOS formation region A1 and a PMOS formation region A2 which are independent from each other, isolated by the element isolation insulating films 2 and 2 formed to penetrate through a SOI layer 3 and the buried oxide film 4 and reach a part of the semiconductor substrate 1. In these NMOS formation region A1 and PMOS formation region A2, a NMOS transistor Q12 and a PMOS transistor Q41 are formed, respectively.

Since the structure of the NMOS transistor Q12 is similar to that of the NMOS transistor Q12 of Embodiment 1 as illustrated in FIG. 15, elements having like function will be identified by like reference numerals and overlapping descriptions will be omitted as needed.

The PMOS transistor Q41 will be described. P type source and drain regions 65 and 65 are formed selectively in the SOI layer 3 of the PMOS formation region A2. Extension regions 66 and 66 are formed adjacently to these source and drain regions 65 and 65 in the direction of a channel.

A gate electrode 62 having an entirely silicided surface is formed over a channel region 24 which is an upper layer portion of the SOI layer 3 between the extension regions 66 and 66 via a gate oxide film 21. The gate electrode 62 has, on the side surface thereof, a sidewall 23. An upper layer portion of the source/drain region 65 is a Ni silicide region 67.

An N type threshold voltage controlling diffusion layer 28 is formed as an upper layer portion of the semiconductor substrate 1 below the channel region 24 and the source/drain regions 65 and 65. In such a manner, the PMOS transistor Q41 having, as main components thereof, the channel region 24, the source/drain region 65, the extension region 66, the gate oxide film 21, and the gate electrode 62 is formed in the PMOS formation region A2.

FIGS. 23 to 28 are cross-sectional views illustrating the manufacturing method of the semiconductor device of Embodiment 3. The manufacturing method of the semiconductor device of Embodiment 3 will next be described based on these drawings.

After similar manufacturing steps to those employed in Embodiment 1 as illustrated in FIGS. 2 to 8, the SOI layer 3 is removed to expose the surface of the buried oxide film 4 by etching or the like with the gate structure, the side spacer 33, and the side wall 13 for NMOS as a mask while covering the PMOS formation region A2 with a silicon oxide film 48 and exposing the NMOS formation region A1, as illustrated in FIG. 23. The buried oxide film 4 is then removed by dry etching or wet etching to expose the surface of the semiconductor substrate 1 (threshold voltage controlling diffusion layer 18). A part of the upper layer portion of the exposed semiconductor substrate 1 is then removed by etching or the like.

As a result, in the NMOS formation region A1, a recess 36 penetrating through the SOI layer 3 and the buried oxide film 4 and reaching a part of the upper layer portion of the semiconductor substrate 1 can be obtained.

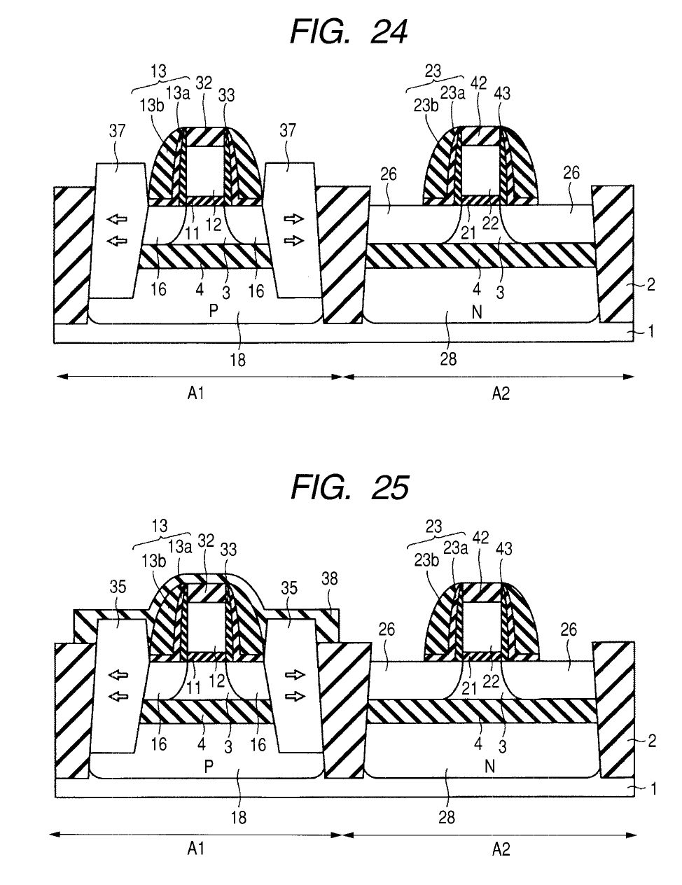

As illustrated in FIG. 24, an SiC epitaxial growth region 37 is formed in a region including the inside of the recess 36 by causing selective epitaxial growth of a material, for example, SiC having a smaller lattice constant than silicon, with single crystal Si of the exposed surface of the semiconductor substrate 1 as a seed.

As illustrated in FIG. 25, the NMOS formation region A1 is covered with a silicon oxide film 38 and the extension region 26 in the PMOS formation region A2 is exposed.

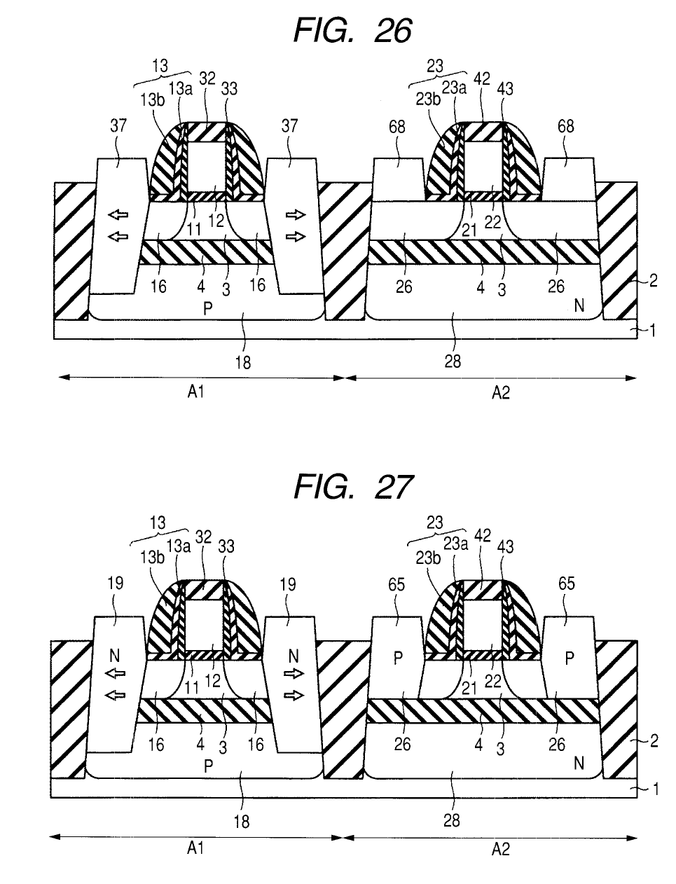

As illustrated in FIG. 26, a Si epitaxial growth region is formed over the extension region 26 by causing selective epitaxial growth from the exposed extension region 26.

As illustrated in FIG. 27, an N type source/drain region 19 is formed by selectively introducing an N type impurity into the SiC epitaxial growth region 37 in the NMOS formation region A1. In a similar manner, a P type source/drain region 65 is formed by selectively introducing a P type impurity into the Si epitaxial growth region 68 and a portion of the extension region 26 in the PMOS formation region A2. Annealing treatment such as RTA is then performed.

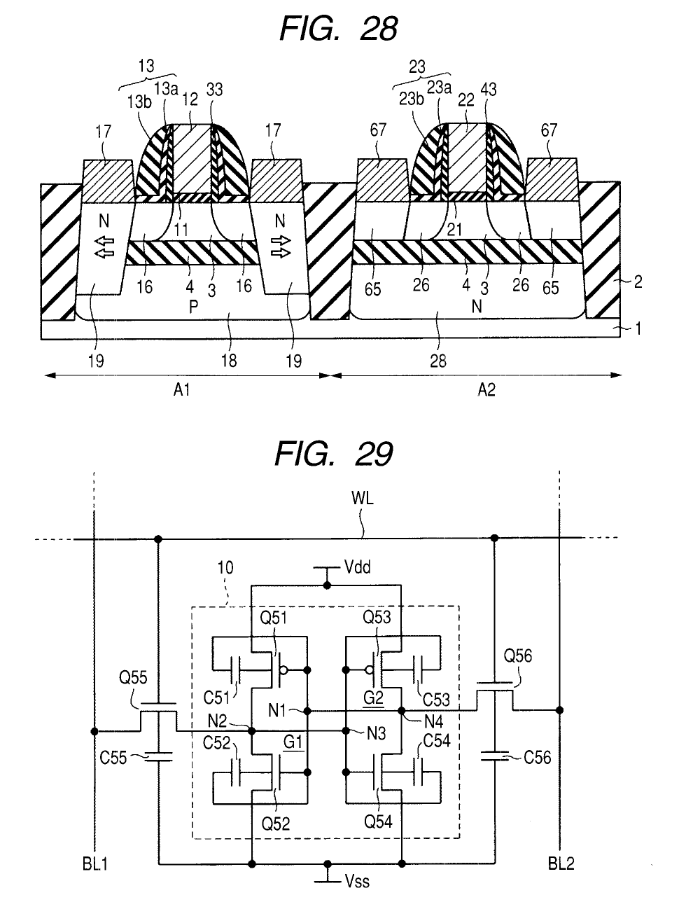

As illustrated in FIG. 28, after removal of the gate protective films 32 and 42, a Ni silicide region 17 and a gate electrode 12 having an entirely silicide surface are formed by siliciding the upper layer portion of the source/drain region 19 and the gate electrode 12 in the NMOS formation region A1. In a similar manner, a Ni silicide region 67 and a gate electrode 22 having an entirely silicided surface are formed by siliciding the upper layer portion of the source/drain region 65 and the gate electrode 22 in the PMOS formation region A2. As a result, manufacture of the semiconductor device of Embodiment 3 as illustrated in FIG. 22 is completed. It should be noted that the side spacers 33 and 43, the silicon oxide films 13a and 23a, and the silicon nitride films 13b and 23b illustrated in FIG. 28 are collectively illustrated as sidewalls 13 and 23 in FIG. 22.

Thus, in the semiconductor device of Embodiment 3, the source/drain region 19 having a tensile strain is formed in the NMOS formation region A1. Since application of a tensile strain can be performed in the NMOS transistor Q12 as in Embodiment 1 or Embodiment 2, this embodiment is effective for enhancing the drive capacity of the NMOS transistor Q12.

The PMOS transistor Q41 is not subjected to strain application treatment for enhancing its drive capacity so that it is inferior to the NMOS transistor Q12 in drive capacity. A CMOS inverter made of the NMOS transistor Q12 and the PMOS transistor Q41 is therefore effective for heightening a β-ratio.

In the NMOS transistor Q12, the source/drain region 19 penetrates through the buried oxide film 4 and reaches a part of the upper layer portion of the semiconductor substrate 1 so that it can have a depth corresponding to the thicknesses of the SOI layer 3 and the buried oxide film 4 and the removed thickness (removed thickness of the semiconductor) of the part of the upper layer portion of the semiconductor substrate 1, making it possible to increase, by the thickness of the buried oxide film 4 and the removed thickness of the semiconductor, the stress (strain) to be applied. As a result, a NMOS transistor Q12 having a source/drain region capable of increasing the drive capacity over that of Embodiment 1 by selective epitaxial growth from the surface of the semiconductor substrate 1 (threshold voltage controlling diffusion layer 18) even if the SOI layer 3 is thinned.

Moreover, since the semiconductor device according to Embodiment 3 has, due to the presence of the buried oxide film 4 partially below the gate electrode 12 (22), a fully depleted type SOI structure and at the same time, has a pseudo double gate structure as in Embodiment 1 or Embodiment 2, the device is excellent in short channel characteristics.

Also in Embodiment 3 similar to Embodiment 1 or Embodiment 2, there occurs no junction leakage due to defects during formation of the SiC epitaxial growth region 37.

Thus, the semiconductor device according to Embodiment 3 is effective for achieving both miniaturization of the device and performance enhancement in a NMOS transistor.

FIG. 29 is a circuit diagram illustrating the configuration of a SRAM circuit portion including a typical SRAM memory cell. As illustrated in FIG. 29, the SRAM memory cell 10 is made of cross-coupled CMOS inverters G1 and G2.

The inverter G1 is made of a PMOS transistor Q51 and a NMOS transistor Q52 coupled in series between a power line Vdd and a ground level line Vss. A node N1 coupled in common to a gate electrode of the PMOS transistor Q51 and a gate electrode of the NMOS transistor Q52 serves as an input portion of the inverter G1, while a node N2 which is a coupling node between a drain of the PMOS transistor Q51 and a drain of the NMOS transistor Q52 serves as an output portion of the inverter G1. A capacitor C51 is placed between the gate electrode and a substrate potential (back gate potential) of the PMOS transistor Q51, while a capacitor C52 is placed between the gate electrode and the substrate potential of the NMOS transistor Q52.

The inverter G2 is, on the other hand, made of a PMOS transistor Q53 and a NMOS transistor Q54 coupled in series between the power line Vdd and the ground level line Vss. A node N3 coupled in common to a gate electrode of the PMOS transistor Q53 and a gate electrode of the NMOS transistor Q54 serves as an input portion of the inverter G2, while a node N4 which is a coupling node between a drain of the PMOS transistor Q53 and a drain of the NMOS transistor Q54 serves as an output portion of the inverter G2. A capacitor C53 is placed between the gate electrode and a substrate potential of the PMOS transistor Q53, while a capacitor C54 is placed between the gate electrode and the substrate potential of the NMOS transistor Q54.

The PMOS transistors Q51 and Q53 function as a load transistor for supplying charges in order to retain data of a SRAM cell 10, while the NMOS transistors Q52 and Q54 function as a drive transistor for driving a node N2 and a node N4 which are storage nodes in order to retain data of the SRAM cell 10.

The node N2 (output portion) of the inverter G1 is coupled with the node N3 (input portion) of the inverter G2, while the node N1 (input portion) of the inverter G1 is coupled with the node N4 (output portion) of the inverter G2. The inverter G1 and the inverter G2 are thus cross-coupled.

A NMOS transistor Q55 is inserted between the node N2 of the SRAM memory cell 10 and a bit line BL1 and the gate electrode of the NMOS transistor Q55 is coupled with a word line WL. A NMOS transistor Q56 is inserted between the node N4 of the SRAM memory cell 10 and a bit line BL2 and the gate electrode of the NMOS transistor Q56 is coupled with the word line WL. A capacitor C55 is placed between the substrate potential of the NMOS transistor Q55 and the ground level line Vss, while a capacitor C56 is placed between the substrate potential of the NMOS transistor Q56 and the ground level line Vss.

The NMOS transistors Q55 and Q56 function as a transfer transistor for accessing the SRAM cell 10. With regards to the power line Vdd and the ground level line Vss, a voltage applied to the power line Vdd is set at, for example, 1.2 V and a voltage applied to the ground level line Vss is set at, for example, 0 V.

The MOS transistors in the SRAM circuit portion as illustrated in FIG. 29 are composed of the NMOS transistor Q12 and the PMOS transistor Q41 of the semiconductor device of Embodiment 3 are employed. Described specifically, the SRAM circuit portion including the SRAM memory cell 10 is composed of the PMOS transistors Q51 and Q53 having an equivalent structure to the PMOS transistor Q41 illustrated in FIG. 22 and the NMOS transistors Q52 and Q54 to Q56 having an equivalent structure to the NMOS transistor Q12 illustrated in FIG. 22. The capacitors C51 and C53 are composed of the SOI layer 3, the buried oxide film 4, and the threshold voltage controlling diffusion layer 28 in the PMOS formation region A2, while the capacitors C52, and C54 to C56 are composed of the SOI layer 3, the buried oxide film 4, and the threshold voltage controlling diffusion layer 18 in the NMOS formation region A1.

The MOS transistors Q51 to Q56 therefore have a fully-depleted SOI transistor structure and at the same time, a pseudo double gate structure. The substrate potential is controlled via the capacitors C51 to C56. The threshold voltage Vth of the MOS transistors Q51 to Q54 can be controlled, as in the control of the substrate potential of a bulk CMOS transistor, by controlling the substrate potential by the potential of the gate electrode.

As described above, enhancement of the drive capacity of only the NMOS transistor in the CMOS inverters G1 and G2 is effective for improving the SNM (Static Noise Margin) characteristics of the SRAM memory cell 10 and enabling stable operation of the cell.

As the NMOS transistor in Embodiment 3, a similar NMOS transistor Q12 to that employed in Embodiment 2 is used. The NMOS transistor Q12 may however be replaced by the NMOS transistor Q11 of Embodiment 1 to apply a strain.

It is also possible to reverse the conductivity type of Embodiment 3 and thereby enhancing the drive capacity of only the PMOS transistor.

### Embodiment 4

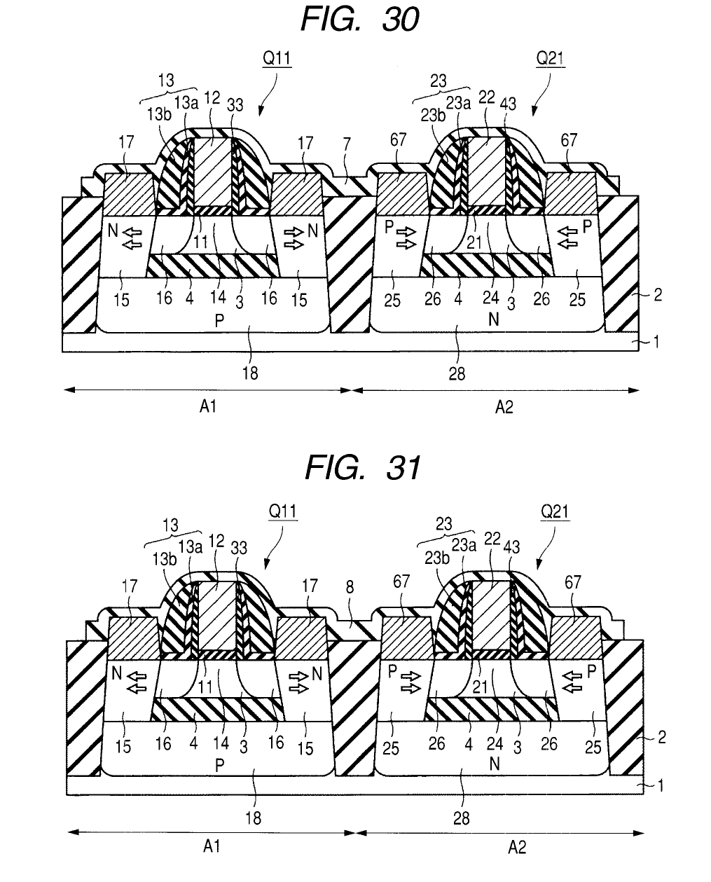

FIG. 30 is a cross-sectional view illustrating the structure of a CMOS semiconductor device of Embodiment 4 according to the present invention having a SOI structure.

As illustrated in this drawing, a silicon nitride liner film 7 is formed on the entire surface including a NMOS formation region A1 and a PMOS formation region A2. Described specifically, the silicon nitride liner film 7 is formed over a gate electrode 12, a sidewall 13 (including a side spacer 33), and a Ni silicide region 17 of a NMOS transistor Q11, and a gate electrode 22, a sidewall 23 (including a side spacer 43), and a Ni silicide region 27 of a PMOS transistor Q21. This silicon nitride liner film 7 functions as a tensile stress application film for applying a tensile stress to a channel region of each of the NMOS transistor Q11 and the PMOS transistor Q21. The structure of each of the NMOS transistor Q11 and the PMOS transistor Q21 is similar to that of Embodiment 1 illustrated in FIG. 1 or FIG. 14, elements having like function will be identified by like reference numerals and overlapping descriptions will be omitted as needed.

As a candidate of a formation method of this silicon nitride liner film 7, a method of forming it over the entire surface after completion of the NMOS transistor Q11 and the PMOS transistor Q21 by the manufacturing method of Embodiment 1 (refer to FIGS. 1 and 14) can be considered.

Thus, it is possible to enhance the drive capacity of the NMOS transistor Q11 further by forming the silicon nitride liner film 7 for applying a tensile stress to the channel region 14.

In Embodiment 4, the silicon nitride liner film 7 is formed in the semiconductor device of Embodiment 1. It is also possible to form the silicon nitride liner film 7 in the semiconductor device of Embodiment 2 or Embodiment 3.

In such a case, the silicon nitride liner film 7 is formed after completion of the MOS transistors Q12 and Q22 (refer to FIGS. 15 and 21) in Embodiment 2 or the NMOS transistors Q12 and Q41 (refer to FIGS. 22 and 28) in Embodiment 3.

### Embodiment 5

FIG. 31 is a cross-sectional view illustrating the structure of a CMOS semiconductor device of Embodiment 5 of the present invention having a SOI structure.

As illustrated in this drawing, a silicon nitride liner film 8 is formed over the entire surface including a NMOS formation region A1 and a PMOS formation region A2. Described specifically, the silicon nitride liner film 8 is formed over a gate electrode 12, a sidewall 13, and a Ni silicide region 17 of a NMOS transistor Q11, and a gate electrode 22, a sidewall 23, and a Ni silicide region 67 of a PMOS transistor Q21. This silicon nitride liner film 8 functions as a compressive stress application film for applying a compressive stress to the NMOS transistor Q11 and the PMOS transistor Q21. The structure of each of the NMOS transistor Q11 and the PMOS transistor Q21 is similar to that of Embodiment 1 illustrated in FIG. 1 or FIG. 14 so that elements having like function will be identified by like reference numerals and overlapping descriptions will be omitted as needed.

As a candidate of a formation method of this silicon nitride liner film 7, a method of forming it over the entire surface after completion of the NMOS transistor Q11 and the PMOS transistor Q21 by the manufacturing method of Embodiment 1 (refer to FIGS. 1 and 14) can be considered.

Formation of the silicon nitride liner film 8 for applying a compressive stress to the channel region 24 is effective for enhancing the drive power of the PMOS transistor Q21 further.

The semiconductor device proposed in Embodiment 5 is similar to the semiconductor device of Embodiment 1 except that the former one has the silicon nitride liner film 8. The semiconductor device of Embodiment 5 may also be similar to the semiconductor device of Embodiment 2 or Embodiment 3 except that the former one has the silicon nitride liner film 8.

In this case, the silicon nitride liner film 8 is formed after completion of the MOS transistors Q12 and Q22 (refer to FIGS. 15 and 21) of Embodiment 2 or completion of the NMOS transistors Q12 and Q41 (refer to FIGS. 22 and 28) of Embodiment 3.

### Embodiment 6

FIG. 32 is a cross-sectional view illustrating the structure of a CMOS semiconductor device of Embodiment 6 of the present invention having a SOI structure.

As illustrated in this drawing, a silicon nitride liner film 9p is formed in the NMOS formation region A1 and a silicon nitride liner film 9c is formed in the PMOS formation region A2. Described specifically, the silicon nitride liner film 9p is formed over a gate electrode 12, a sidewall 13, and a Ni silicide region 17 of a NMOS transistor Q11, while the silicon nitride liner film 9c is formed over a gate electrode 22, a sidewall 23, and a Ni silicide region 67 of a PMOS transistor Q21.

The silicon nitride liner film 9p functions as a tensile stress application film for applying a tensile stress to a channel region 14 of the NMOS transistor Q11, while the silicon nitride film 9c functions as a compressive stress application film for applying a compressive stress to a channel region 24 of the PMOS transistor Q21. The structures of the NMOS transistor Q11 and the PMOS transistor Q21 are similar to those of Embodiment 1 illustrated in FIGS. 1 and 14 so that elements having like function will be identified by like reference numerals and overlapping descriptions will be omitted as needed.

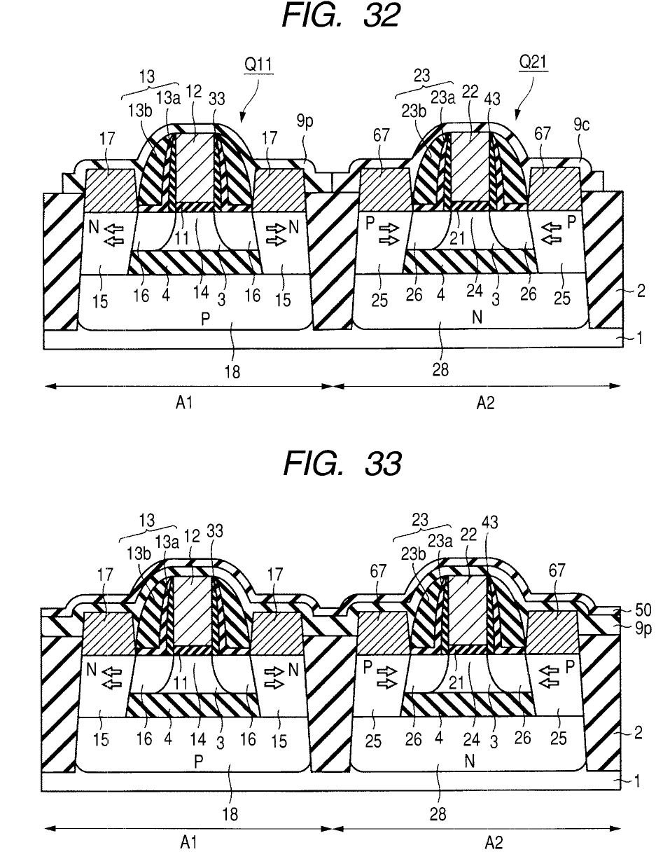

FIGS. 33 to 36 are cross-sectional views illustrating the manufacturing method of a semiconductor device of Embodiment 6. FIGS. 33 to 36 illustrate steps after completion of the NMOS transistor Q11 and the PMOS transistor Q21 (refer to FIG. 1 and FIG. 14) in accordance with the manufacturing method (FIGS. 2 to 14) of Embodiment 1.

First, as illustrated in FIG. 33, a silicon nitride liner film 9p having a tensile stress is deposited over the entire surface. A silicon oxide film 50 is formed over the resulting silicon nitride liner film 9p.

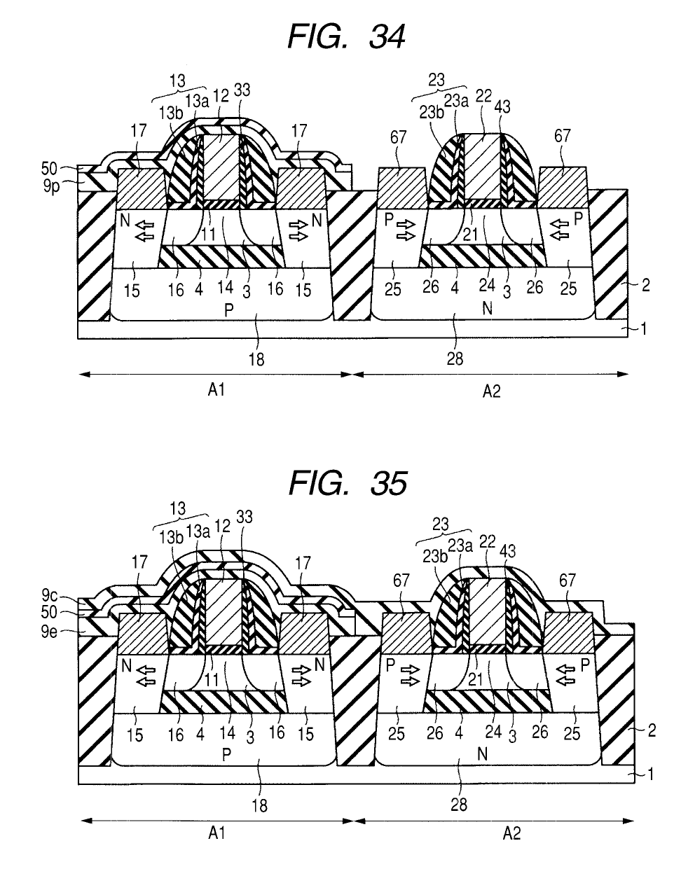

As illustrated in FIG. 34, resist application and patterning treatment are performed to form an opening only in the PMOS formation region A2. The silicon nitride liner film 9p and the silicon oxide film 50 are selectively removed from the PMOS formation region A2 by etching.

As illustrated in FIG. 35, a silicon nitride liner film 9c having a compressive stress is deposited over the entire surface. It should be noted that the formation of the silicon nitride liner film 9c and the silicon nitride liner film 9p which are different from each other in a stress direction can be realized by setting the film formation conditions as needed.

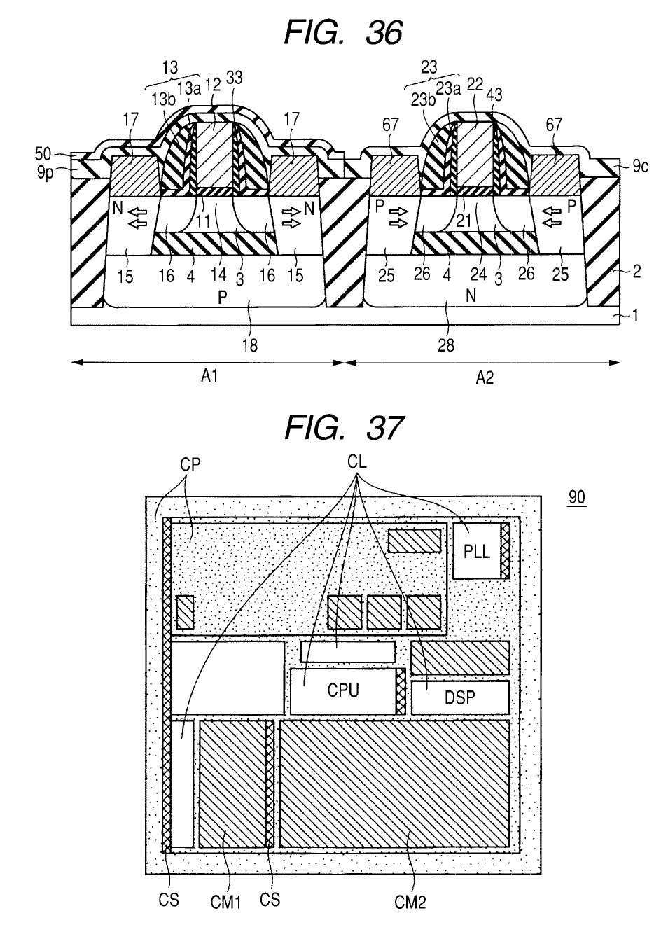

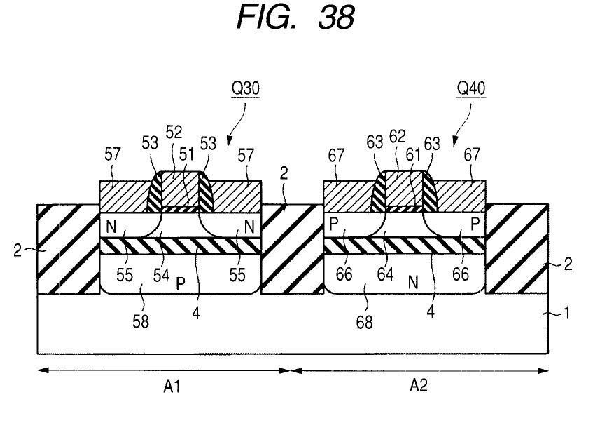

As illustrated in FIG. 36, resist application and patterning treatment are performed to form an opening only in the NMOS formation region A1. The silicon nitride liner film 9p is selectively removed from the NMOS formation region A1 by etching. During etching, the silicon oxide film 50 functions as a stopper and prevents removal of the silicon nitride liner film 9p.

The silicon oxide film 50 is then removed from the NMOS formation region A1 to complete the semiconductor device of Embodiment 6 wherein the silicon nitride liner film 9p and the silicon nitride liner film 9c are selectively formed in the NMOS formation region A1 and the PMOS formation region A2, respectively.

Formation of the silicon nitride liner film 9p for applying a tensile stress to the channel region 14 of the NMOS formation region A1 is effective for enhancing the drive capacity of the NMOS transistor Q11 further.

In addition, formation of the silicon nitride liner film 9c for applying a compressive stress to the channel region 24 of the PMOS formation region A2 is effective for enhancing the drive capacity of the PMOS transistor Q21 further.

The semiconductor device according to Embodiment 6 is similar to that of Embodiment 1 except that the former one has the silicon nitride liner films 9p and 9c. It may be similar to the semiconductor device of Embodiment 2 or Embodiment 3 except that the former one has both the silicon nitride liner films 9p and 9c.

In this case, the silicon nitride liner film 9p is formed in the NMOS formation region A1 and the silicon nitride liner film 9c is formed in the PMOS formation region A2 after completion of the MOS transistors Q12 and Q22 (refer to FIGS. 15 and 21) of Embodiment 2 or completion of the NMOS transistors Q12 and Q41 (refer to FIGS. 22 and 28) of Embodiment 3.

### Application Embodiment

FIG. 37 is a schematic view illustrating the circuit configuration of a system LSI which is an application example of the present invention. As illustrated in FIG. 37, a system LSI 90 integrates therein a logic circuit portion CL (PLL circuit, CPU, DSP, and the like), a high-speed memory portion CM1, a large-capacity memory portion CM2, a power off switch portion CS, and a peripheral circuit portion CP.

The present invention is applied to such a system LSI 90, for example, by configuring the logic circuit portion CL by the semiconductor device of Embodiment 1 or Embodiment 2 and configuring a SRAM memory cell in the high-speed memory portion CM1 or large-capacity memory portion CM2 by the semiconductor device of Embodiment 3. The system LSI 90 having such a configuration is effective for enhancing the drive capacity of the logic circuit portion CL and enabling the SRAM in the high-speed memory portion CM1 or the large-capacity memory portion CM2 to exhibit good SNM characteristics.

### Other embodiments

In the above-described embodiments, it is desired to form the buried oxide film 4 while adjusting its thickness to from approximately 10 to 15 nm.

The present invention can also be applied to a typical SOI structure having a thicker buried oxide film 4 and having no threshold voltage controlling diffusion layer 18 (28). Described specifically, the present invention can also be achieved by a modified structure obtained, in the above-described typical SOI structure, by forming the NMOS transistor Q11 and the PMOS transistor Q21 so as to pass through the buried oxide film and forming the NMOS transistor Q12 and the PMOS transistor Q22 in the buried oxide film and a part of the upper layer portion of the semiconductor substrate. In this case, a parasitic capacitance due to the buried oxide film can be reduced by increasing the thickness of the buried oxide film.

It is theoretically possible to replace the steps illustrated in FIGS. 9 to 12 (or FIGS. 16 to 19 of Embodiment 2) in the manufacturing method of the semiconductor device according to Embodiment 1 by the following modified method. This modified method comprises forming a recess 34 (36) and a recess 44 (46) of the NMOS formation region A1 and the PMOS formation region A2 simultaneously and performing the selective epitaxial growth treatment of the SiC epitaxial growth region 35 (37) in the NMOS formation region A1 and the selective epitaxial growth treatment of the SiGe epitaxial growth region 45 (47) in the PMOS formation region A2.

When this modified method is employed, however, a protective film such as silicon oxide film must be formed directly on either one of the recesses 34 and 44. The covering accuracy of the protective film which must be formed on the recess reduces and gives damage to the lower layer portion during removal of the protective film formed on the recess.

For example, when the PMOS formation region A2 is covered and protected with a protective film such as silicon oxide film during formation of the SiC epitaxial growth region 35 in the recess 34, the protective film must be formed directly in the recess 44. This increases the surface unevenness of the PMOS formation region A2 and reduces the covering accuracy of the protective film. In addition, during removal of the protective film, it gives damage to the threshold voltage controlling diffusion layer 28 just below the protective film.

Accordingly, it is preferred to carry out a formation step of the recess 34 and a formation step of the recess 44 independently as illustrated in FIGS. 9 to 12 in consideration of minus factors such as reduction of covering accuracy of the protective film and damage to the lower layer portion during removal of the protective film.

What is claimed is:

1. A semiconductor device comprising:
a first-conductivity-type first MOS transistor having a SOI structure including a semiconductor substrate, a buried insulating film, and a SOI layer and having a principal portion of the MOS transistor in the SOI layer,
wherein the first MOS transistor includes:
a first channel region formed selectively in the surface of the SOI layer; and
first-conductivity-type first source and drain regions formed with the first channel region therebetween,
wherein the first source and drain regions are made of a first strain application material for applying to the first channel a strain for improving the driving capacity,
wherein a first gate oxide film formed over the first channel region and a first gate electrode formed over the first gate oxide film are further provided, and
wherein the first source and drain regions penetrate the buried insulating film.

2. The semiconductor device according to claim 1, wherein the first source and drain regions reach even an upper layer portion of the semiconductor substrate.

3. The semiconductor device according to claim 1, wherein the first MOS transistor has, in the upper layer portion of the semiconductor substrate, a second-conductivity-type first diffusion region in at least a region corresponding to the first channel region.

4. The semiconductor device according to claim 1, further comprising, over the first MOS transistor, a stress application film for applying a strain to the first channel region for improving the drive capacity.

5. The semiconductor device according to claim 1, further comprising:
a second-conductivity-type second MOS transistor having a principal portion thereof in the SOI layer,
wherein the SOI structure has first and second MOS formation regions which are independently from each other,
wherein the first and second MOS transistors are formed in the first and second MOS formation regions;
wherein the second MOS transistor includes:
a second channel region selectively formed in the surface of the SOI layer; and
second-conductivity-type second source and drain regions formed with the second channel region therebetween,
wherein the second source and drain regions are formed of a second strain application material for applying to the second channel region a strain for improving the drive capacity,
wherein a second gate oxide film formed over the second channel region and a second gate electrode formed over the second gate oxide film are further provided, and
wherein the second source and drain regions penetrate through the buried insulating film.

6. The semiconductor device according to claim 2, further comprising:
a second-conductivity-type second MOS transistor having a principal portion thereof in the SOI layer,
wherein the SOI structure has first and second MOS formation regions which are independently from each other,
wherein the first and second MOS transistors are formed in the first and second MOS formation regions,
wherein the second MOS transistor is equipped with a second channel region selectively formed in the surface of the SOI layer and a second-conductivity-type second source and drain regions formed with the second channel region therebetween,
wherein the second source and drain regions are formed of a second strain application material for applying to the second channel region a strain for improving the drive capacity,
wherein the second MOS transistor is equipped further with a second gate oxide film formed over the second channel region and a second gate electrode formed over the second gate oxide film, and
wherein the second source and drain regions penetrate through the buried insulating film and at the same time, reach a part of an upper layer portion of the semiconductor substrate.

7. The semiconductor device according to claim 1, further comprising:
a second-conductivity-type second MOS transistor in the SOI layer,
wherein the SOI structure has first and second MOS formation regions which are independent from each other,
wherein the first and second MOS transistors are formed in the first and second MOS formation regions, and
wherein the second MOS transistor includes:
a second channel region formed selectively in the surface of the SOI layer;
second-conductivity-type second source and drain regions formed in the SOI layer with the second channel region therebetween;
a second gate oxide film formed over the second channel region; and
a second gate electrode formed over the second gate oxide film.

8. The semiconductor device according to claim 5, wherein the second MOS transistor has a second-conductivity-type second diffusion region in at least a region corresponding to the second channel region in the upper layer portion of the semiconductor substrate.

9. The semiconductor device according to claim 5, further comprising a stress application film formed over the first and second MOS transistors and applying, to the first channel region, a strain for improving the drive capacity.

10. The semiconductor device according to claim 5, further comprising:
a first stress application film formed over the first MOS transistor and applying, to the first channel region, a strain for improving the drive capacity; and
a second stress application film formed over the second MOS transistor and applying, to the second channel region, a strain for improving the drive capacity.

11. A manufacturing method of a semiconductor device, comprising a first-conductivity-type first MOS transistor having a SOI structure including a semiconductor substrate, a buried insulating film, and a SOI layer and having a principal portion of the MOS transistor in the SOI layer, comprising the steps of:
(a) preparing the SOI structure having a first MOS formation region;
(b) selectively forming a first gate oxide film over the surface of the SOI layer in the first MOS formation region and a first gate electrode over the first gate oxide film, wherein an upper layer portion of the SOI layer below the first gate electrode is defined as a first channel region;
(c) forming first sidewalls over the side surfaces of the first gate electrode;
(d) forming, in the first MOS formation region, a first recess which penetrates through the SOI layer and the buried oxide film, with the first gate electrode and the first sidewall as a mask;
(e) forming, in the first recess, a first epitaxial growth region including a first strain application material for applying, to the first channel region, a strain for improving the drive capacity by the epitaxial growth from the surface of the semiconductor substrate below the first recess; and
(f) introducing a first-conductivity-type impurity into the first epitaxial growth region to form first-conductivity-type first source and drain regions.

12. The manufacturing method of a semiconductor device according to claim 11, wherein the first recess formed by the step (d) further includes the upper layer portion of the semiconductor substrate.

13. The manufacturing method of a semiconductor device according to claim 11, further comprising a step of:
(g) after the step (a) but prior to the step (b), in the first MOS formation region, introducing a second-conductivity-type impurity into at least the upper lower portion of the semiconductor substrate opposite to the first channel region with the buried insulating film therebetween to form a second-conductivity-type first diffusion region.

14. The manufacturing method of a semiconductor device according to claim 11, further comprising a step of:
(h) after the step (f), forming, over the first MOS transistor in the first MOS formation region, a stress application film for applying a strain for improving the drive capacity to the first channel region.

15. The manufacturing method of a semiconductor device according to claim 11,
wherein the semiconductor device further comprises a second-conductivity-type second MOS transistor having a principal portion thereof in the SOI layer,
wherein the SOI structure further comprises, independently from the first MOS formation region, a second MOS formation region for forming the second MOS transistor,
wherein the step (b) further comprises a step of selectively forming a second gate oxide film over the surface of the SOI layer in the second MOS formation region and a second gate electrode over the second gate oxide film,
wherein an upper layer portion of the SOI layer below the second gate electrode is defined as a second channel region,
wherein the step (c) further comprises a step of forming second sidewalls over the side surfaces of the second gate electrode,
the manufacturing method of the semiconductor device further comprising the steps of:
(i) forming, in the second MOS formation region, a second recess which penetrates the SOI layer and the buried insulating film, with the second gate electrode and the second sidewalls as a mask; and
(j) forming, in the second recess, a second epitaxial growth region including a second strain application material for applying to the second channel region a strain for improving the drive capacity by the epitaxial growth from the upper layer portion of the semiconductor substrate below the second recess,
wherein the step (f) is performed after the step (j) and further comprises a step of introducing a second-conductivity-type impurity into the second epitaxial growth region to form second-conductivity-type second source and drain regions.

16. The manufacturing method of a semiconductor device according to claim 12,
wherein the semiconductor device further comprises a second-conductivity-type second MOS transistor having a principal portion thereof in the SOI layer,
wherein the SOI structure further comprises, independently from the first MOS formation region, a second MOS formation region for forming the second MOS transistor,
wherein the step (b) further comprises a step of selectively forming a second gate oxide film over the surface of the SOI layer in the second MOS formation region and a second gate electrode over the second gate oxide film,
wherein an upper layer portion of the SOI layer below the second gate electrode is defined as a second channel region,
wherein the step (c) further comprises a step of forming second sidewalls over the side surfaces of the second gate electrode,
the manufacturing method of the semiconductor device further comprising the steps of:
(i) forming, in the second MOS formation region, a second recess which penetrates through the SOI layer and the buried insulating film and reaching the upper layer portion of the semiconductor substrate, with the second gate electrode and the second sidewalls as a mask; and
(j) forming, in the second recess, a second epitaxial growth region including a second strain application material for applying to the second channel region a strain for improving the drive capacity by the epitaxial growth from the upper layer portion of the semiconductor substrate below the second recess,
wherein the step (f) is performed after the step (j) and further comprises a step of introducing a second-conductivity-type impurity into the second epitaxial growth region to form second-conductivity-type second source and drain regions.

17. The manufacturing method of a semiconductor device according to claim 11,
wherein the semiconductor device further comprises a second-conductivity-type second MOS transistor,
wherein the SOI structure further comprises, independently from the first MOS formation region, a second MOS formation region for forming the second MOS transistor,
wherein the step (b) further comprises a step of selectively forming a second gate oxide film over the surface of the SOI layer in the second MOS formation region and a second gate electrode over the second gate oxide film,
wherein an upper layer portion of the SOI layer below the second gate electrode is defined as a second channel region,
wherein the step (c) further comprises a step of forming second sidewalls over the side surfaces of the second gate electrode, and
wherein the step (f) further comprises a step of introducing a second-conductivity-type impurity into the SOI layer with the second gate electrode and the sidewalls as a mask to form second-conductivity-type second source and drain regions.

18. The manufacturing method of a semiconductor device according to claim 15, further comprising a step of:
(k) after the step (a) but prior to the step (b), in the second MOS formation region, introducing a first-conductivity-type impurity into at least the upper layer portion of the semiconductor substrate opposing to the second channel region with the buried insulating film therebetween to form a first-conductivity-type second diffusion region.

19. The manufacturing method of a semiconductor device according to claim 15, further comprising a step of:
(l) after the step (f), forming, over the first and second MOS transistors in the first and second MOS formation regions, a stress application film for applying to the first channel region a strain for improving the drive capacity.

20. The manufacturing method of a semiconductor device according to claim 15, further comprising the steps of:
(l-1) after the step (f), forming, over the first MOS transistor in the first MOS formation region, a first stress application film for applying to the first channel region a strain for improving the drive capacity; and
(l-2) after the step (f), forming, over the second MOS transistor in the second MOS formation region, a second stress application film for applying to the second channel region a strain for improving the drive capacity.
